(19) United States
(12) Patent Application Publication
(10) Pub. No.: US 2005/0104187 A1
(43) Pub. Date: May 19, 2005

(54) Redistribution of substrate interconnects

(76) Inventors: Cynthia H. Polsky, Chandler, AZ (US); Terry Sterrett, Cave Creek, AZ (US); Johanna M. Swan, Scottsdale, AZ (US)

Correspondence Address: SCHWABE, WILLIAMSON & WYATT, P.C.;PACWEST CENTER, SUITES 1600-1900, 1211 SW FIFTH AVENUE, PORTLAND, OR, 97204, US

(21) Appl. No.: 10/698,837

(22) Filed: Oct. 31, 2003

(51) Int. Cl. H01L 23/48

(52) U.S. Cl. 257/690

(57) ABSTRACT

A first die/substrate is provided with a backside interconnect. A redistribution layer is provided between the first die/substrate and a second die/substrate that is stacked thereon, which includes a redistributed interconnect of the backside interconnect, coupled to and offset from the backside interconnect.

### FIELD OF THE INVENTION

The present invention relates to semiconductor devices, and, more particularly, to the redistribution of interconnects of a substrate to enable coupling between two substrates having misaligned interconnects or internal conductive traces.

### BACKGROUND

Semiconductor devices, such as, but not limited to, microelectronic, micro-optoelectronic, and microelectromechanical systems (MEMS), share a common fabrication technology comprising the use of a substrate with multiple interlayers of conductive, semiconductive, and/or insulative materials that form electrically interconnected pathways and microcircuits. Such substrates may be produced in a wide range of configurations and materials, from silicon and compound semiconductor wafers upon which nanometer-scale devices may be formed to create what is referred to as a die, to organic and ceramic interposers and carrier substrates that are used to electrically couple dies with other substrates to create what is known as a package.

A package comprises at least one die electrically interconnected with a carrier substrate and one or more other elements, such as, but not limited to, an integrated heat spreader and/or socket interconnects. Packages include, but are not limited to, microelectronic packages, microelectromechanical systems (MEMS) and optoelectronic packages packages. An example of a microelectronic package is an integrated circuit microprocessor, which comprises a microelectronic die.

Signals paths within the die commonly terminate at one surface of the substrate, referred to as the active side, in the form of discrete metallized portions referred to as interconnects or surface interconnects. Interconnects on die are also referred to as land pads, and on substrates as bond pads, and similar variants and combinations, and often generally referred to as interconnects. These are considered equivalent terms for the purpose of this disclosure. The interconnects provide a surface upon which electrically conductive interconnect material is used to form a physical connection between interconnects of one substrate and corresponding interconnects of another substrate.

The land pads on the die were traditionally located on the active side about the peripheral edge of the substrate. The corresponding carrier substrate bond pads were located such that they would encircle the die when the die backside was adhesively bonded to the carrier substrate. Interconnection was made by welding wire between the land pads and the bond pads. Such wires, commonly made of gold, have been referred to as bond wires, and the process referred to as wire bonding. This type of interconnection occupies an unacceptably large portion of the carrier substrate.

A modern approach to die-to-carrier substrate interconnection is known as surface mount technology (SMT). Examples of SMT electrical components include, but are not limited to, flip chip-ball grid array (FC-BGA) packaging and chip-scale packaging. Surface mount technology electrical components are widely used because of their compact size and simplicity of interconnection.

Surface mount technology provides land pads on the active side of a die that are in one-for-one opposing relationship regarding location, size and shape with the bond pads of a carrier substrate. The land pads of the first die may be interconnected with opposing bond pads on the carrier substrate.

It is not uncommon that the interconnects of one substrate are not in opposing alignment with the interconnects of a second substrate, precluding direct interconnection without modification. In some applications, a redistribution layer (RDL) is formed over an interconnect and adjacent portion of the insulator layer of one substrate to provide a path or link to the misaligned opposing interconnect of the second substrate. Redistribution layers can take many forms, including metallized traces (e.g. doglegs), and interposers which are separate substrates in themselves.

The trend for higher density packaging has lead to the concept of stacking one die on top of another die in a vertical orientation. The land pads of a first die are interconnected with bond pads on the carrier substrate using an appropriate process, such as, but not limited to, a conventional controlled collapse chip connection (C4) reflow process, compression bonding, ultrasonic bonding, and conductive adhesive. A second die backside of a second die is coupled to a first die backside of the first die, such as by using adhesive. The interconnects of the second die are interconnected with interconnects on the carrier substrate using wire-bonding. Though, this process provides a stacked configuration for the two die, carrier substrate surface area is still taken up by the bond pads that are wire-bonded to the second die. This process produces a package with undesirable form factor and inherent fragility of the wire-bonds which effects product reliability.

### BRIEF DESCRIPTION OF THE DRAWING

The invention is illustrated by way of example and not by way of limitation in the figures of the accompanying drawings, in which the like references indicate similar elements and in which:

FIG. 1 is a cross-sectional view of a die with a via, in accordance with an embodiment of the invention;

FIG. 2 is a cross-sectional view of the die after the application of a conductive layer on the die backside, in accordance with an embodiment of the invention;

FIG. 3 is a cross-sectional view of the die with patterned conductive layer post etch and resist removal, in accordance with an embodiment of the invention;

FIG. 4 is a cross-sectional view of the die with patterned dielectric layer defining lateral interconnects that are complimentary with the pattern of a second die interconnects on a second die, in accordance with embodiments of the invention;

FIG. 5 is a cross-sectional view of the die with a redistribution layer, in accordance with embodiments of the invention; and

FIG. 6 is a cross-sectional view of a die assembly with a redistribution layer, in accordance with embodiments of the invention.

### DETAILED DESCRIPTION OF EMOBODIMENTS OF THE INVENTION

In the following detailed description, reference is made to the accompanying drawings which form a part hereof wherein like numerals designate like parts throughout, and in which is shown by way of illustration specific embodiments in which the invention may be practiced. It is to be understood that other embodiments may be utilized and structural or logical changes may be made without departing from the scope of the present invention. Therefore, the following detailed description is not to be taken in a limiting sense, and the scope of the present invention is defined by the appended claims and their equivalents.

In the following detailed description, reference is made to the accompanying drawings which form a part hereof wherein like numerals designate like parts throughout, and in which is shown by way of illustration specific embodiments in which the invention may be practiced. It is to be understood that other embodiments may be utilized and structural or logical changes may be made without departing from the scope of the present invention. Therefore, the following detailed description is not to be taken in a limiting sense, and the scope of the present invention is defined by the appended claims and their equivalents.

In the following description, the term “device” is used to identify the discrete layer or layers of material that individually, and in combination, can take many forms, such as, but not limited to, a diode, transistor, FET, optical switches, and other microelectronic, optoelectronic, and microelectromechanical systems (MEMS). The embodiments of the present invention may be practiced for many applications requiring the interconnection of misaligned interconnects, and therefore, the present invention is not to be limited to-the devices and/or materials described by way of example.

The interconnects of a die are commonly a plurality of metallized portions on one side of the die substrate arranged in a pattern commonly referred to as an array. Examples of an array include, but not limited to, a peripheral array wherein the interconnects are arranged about the peripheral edge of the die, and also a staggered array, wherein the interconnects are arranged in a square forming diagonal rows rather than horizontal and vertical rows.

The terms metal layer, metal line, metal trace, conductive trace, conductor, signal path and signaling medium are all related. The related terms listed above are generally interchangeable, and appear in order from specific to general. In this field, metal lines are sometimes referred to as metal or conductive traces, layer, wires, lines, interconnect or simply metal or conductor. Metal lines, generally aluminum (Al), copper (Cu) and alloys of Al and Cu, among many other metals and alloys, are conductors that provide signal paths for coupling or interconnecting electrical circuitry. Conductors other than metal are available in microelectronic devices. Materials such as doped polysilicon, doped single-crystal silicon (often referred to simply as diffusion, regardless of whether such doping is achieved by thermal diffusion or ion implantation), titanium (Ti), molybdenum (Mo), and refractory metal suicides, among many others, are examples of other conductors.

The terms contact and via refer to structures for electrical interconnection of conductors from different interconnect levels such as those found within die and substrate. These terms are sometimes used in the art to describe both an opening in an insulator in which the structure will be completed, and the completed structure itself. For purposes of this disclosure, contact and via refer to the completed structure, and via aperture refers to the opening in an insulator in which the structure is formed.

Substrate, as used herein, refers to the physical object which is the basic workpiece that is transformed by various process operations into the desired micro-component configuration, such as a die. A substrate may also be referred to as a wafer. Wafers may be made of semiconducting, non-semiconducting, or combinations of semiconducting and non-semiconducting materials. Examples of substrates include, among others, wafers comprising silicon (Si), gallium arsenide (GaAs), Indium Phosphate (InP), and their derivations.

Embodiments of the present invention are directed towards electrical interconnection of two or more substrates that do not necessarily have interconnects in a one-to-one aligned corresponding geometrical relationship. These substrate interconnect combinations include, but are not limited to, die-to-die, die-to-carrier substrate, and carrier substrate-to-carrier substrate. By way of example and to illustrate various aspects of embodiments of the present invention, substrate in the form of die will be discussed, and in this example, is directed towards the electrical interconnection of two or more stacked die, wherein the die do not necessarily have interconnects in a one-to-one aligned corresponding geometrical relationship, or wherein one die does not have interconnects on the desired side of the substrate. Other embodiments in accordance with the present invention allow die of varying size and interconnect layout to be made compatible for direct die on die stacking.

It is appreciated that interconnects of one substrate can be misaligned with interconnects of a second substrate that are to be coupled together, regardless of which two sides of the substrate that are the object of the interconnection. In the following embodiments, interconnects on the active side of a second die are to be coupled to interconnects on the back side of a first die that must be created. Embodiments of the present invention are applicable in a general sense regardless of which side of the substrate that interconnects are to be coupled, whether the sides have interconnects or not. Various die side to die side combinations, include, but are not limited to, active side to back side, back side to back side, and active side to active side. Where a side has no interconnects, embodiments of the present invention provide methods for creating interconnects where there is none.

A first die is provided with backside interconnects that are in electrical communication with internal conductive traces. A redistribution layer is provided between the first die and the second die that is stacked thereon. The redistribution layer provides electrically conductive lateral redistribution traces that are interconnected with the backside interconnects on the first die, and extend laterally along the die backside to a location that corresponds to corresponding second die interconnects on the second die. The lateral redistribution traces are provided with a dielectric layer with an aperture that define lateral interconnects in aligned correspondence with the second die interconnects of the second die. In this way, the redistribution layer provides for the interconnection of non-aligned interconnects, acting as an adapter between the two sets of interconnects.

In the following figures, only one interconnect pair is shown. It is understood that this is done for simplicity and in actuality, many hundreds or thousands of interconnects may be located on a surface of a die.

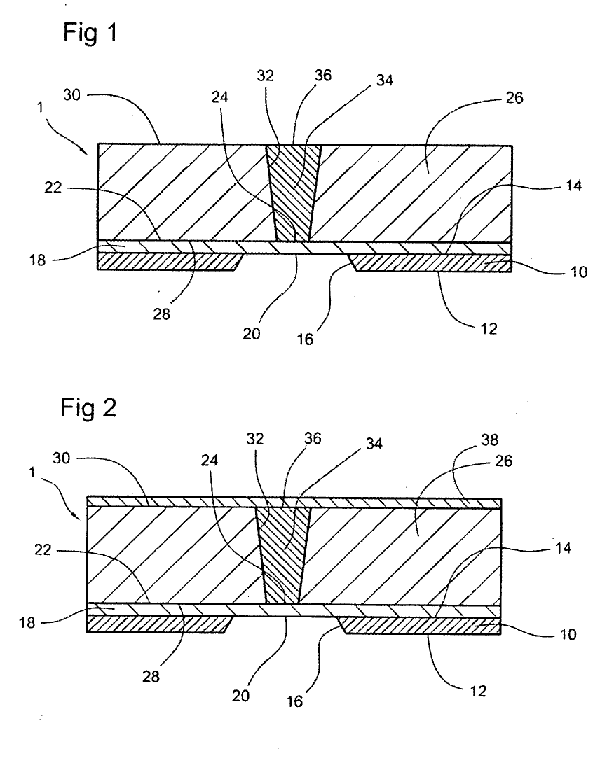

FIG. 1 is a side cross-sectional view of a die 1 in accordance with an embodiment of the invention. The die 1 comprises a first dielectric layer 10, a second dielectric layer 26, and an internal metal layer 18 there between. The internal metal layer 18 has a first metal side 14 and a second metal side 22. For sake of simplicity, the internal metal layer 18 is used to provide a representation of the complex network of internal conductive traces (not shown) that are provided within die 1. It is anticipated that a die 1 may comprise a plurality of internal conductive traces and corresponding inter-level dielectric layers in a stacked relationship.

The first metal side 14 comprises an active side interconnect 20, defined by an active side interconnect aperture 16 formed in the first dielectric layer 10. The active side interconnect 20 is also referred to as a surface interconnect as it forms a part of the surface of the active side. The active side interconnect 20 is in electrical communication with one or more internal conductive traces (not shown) within the internal metal layer 18. The side of the die 1 comprising the active side interconnect 20 is referred to as the active side 12, which is adapted to be placed in facing relationship and interconnected with an interconnect of another micro-component, such as, but not limited to, bond pads on a carrier substrate (not shown), and/or land pads of a die 1.

The active side interconnect 20 may be formed by any one of many processes. In one method, the active side interconnect 20 comprises electrically conductive material, such as gold, silver, and copper, among others, which is deposited onto the internal metal layer 18 and in contact with one or more internal conductive traces (not shown), in a separate process, including but not limited to, photolithographic and screen printing techniques. In another method in accordance with an embodiment of the invention, the active side interconnect 20 comprises the same material and is formed during the same process as the internal conductive traces (not shown).

The second metal side 22 is in electrical communication with a via 34 defined by a via aperture 32 in the second dielectric layer 26. The via 34 is electrically coupled to one or more internal conductive traces (not shown) on the second metal side 22 of the internal metal layer 18 at a first via contact 24 and terminates to form a backside interconnect 36 on a die backside 30 of the die 1. The via 34 comprises an electrically conductive material that provides an electrically conductive conduit for signal coupling between the internal conductive traces of the internal metal layer 18 and the backside interconnect 36. The die 1 is processed by suitable methods to form the backside interconnect 36 in electrical contact with the internal conductive traces of the internal metal layer 18.

Vias 34 may be electrically conductive conduits that extend to one or more metal layers 18. A via aperture 32 is formed, for example, by chemical etching processes, to produce bore holes extending from a backside 30 of the substrate through to an underlying metal layer 18. The via apertures 32 are subsequently plated and/or filled with an electrically conductive material which defines a via 34.

The via 34 can be specified where a particular micro-component substrate does not have surface interconnects on a particular side. A desired predetermined location on the backside 30 is made to correspond to the location of a corresponding interconnect on another micro-component substrate to be interconnected there to. The via aperture 32 is produced perpendicular to the backside 30 directly to the underlying metal layer 18. If the resulting location of the backside interconnect 36 is in alignment with the corresponding interconnect, it is said to be in the predetermined location. If the backside interconnect is not in alignment, the location is referred to as an intermediate location.

FIG. 2 is a side cross-sectional view of the die 1 of FIG. 1 showing an electrically conductive layer 38 deposited on the die backside 30 and electrically coupled to the backside interconnect 36, in accordance with an embodiment of the invention. The electrically conductive layer 38 comprises a material suitable as a signaling medium as defined herein, such as, but not limited to, metal, metal alloys and non-metal conductors. The material may be deposited, for example, by sputtering and/or plating.

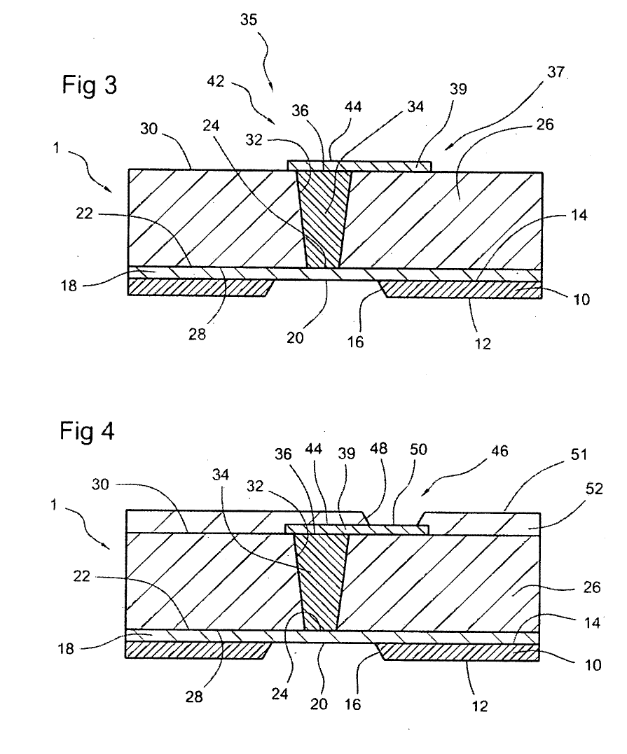

FIG. 3 is a side cross-sectional view of the die 1 of FIG. 2 showing the electrically conductive layer 38 patterned to define a lateral conductive trace 39, in accordance with an embodiment of the invention. The lateral conductive trace 39 is formed by, for example, photolithographic processes. One exemplary photolithographic process involves depositing a mask layer (not shown) in the form of a photoresist layer, or dry film, over the electrically conductive layer 38. The photoresist layer is photoactive, such that when exposed to light, such as, but not limited to, ultraviolet light, the photoresist layer either becomes soluble, in the case of a positive photoresist, or insoluble, in the case of a negative photoresist, in specific solvents.

Light is projected through a template that shields specific areas of the photoresist while exposing other areas, thereby projecting the pattern of the template onto the photoresist layer. After exposure, an appropriate solvent removes the targeted portions of the photoresist layer. The remaining photoresist layer becomes a mask (not shown) that remains on the electrically conductive layer 38. The mask is used to expose areas of the electrically conductive layer 38 to a removal process, such as, but not limited to, a chemical etch process, removing exposed portions of the electrically conductive layer 38 while protecting desired portions of the electrically conductive layer 38 that ultimately form the lateral conductive traces 39, as shown in FIG. 3.

Alternatively, semiconductor components, such as components for optoelectronic applications, frequently use layered heterostructures of semiconductor materials (e.g. PN junction or multi-quantum wells) where semiconductor devices are mostly built from layer upon layer in the vertical direction on a substrate. The layers are selectively deposited and selectively removed using various deposition and material removing processes. These layers can be on the order of nanometers to micrometers in thickness. The methods are used to create microelectronic semiconductor devices, such as diodes and transistors, on the substrate.

The lateral conductive trace 39 defines an electrical path from the backside interconnect 36 to a predetermined location 37 in accordance with a location of a desired corresponding second die interconnect on a second die (not shown). The mask is removed using known techniques. As shown in the illustrated embodiment, the location of the backside interconnect 36, referred to as an intermediate location 35, does not represent the location of the resulting interconnect 50 (shown in FIG. 4).

FIG. 4 is a side cross-sectional view of the die 1 of FIG. 3 showing a third dielectric layer 52, such as a photo-definable layer, formed on the die backside 30 and patterned over the lateral conductive trace 39, in accordance with an embodiment of the invention. The lateral conductive trace 39 and the third dielectric layer 52 define a redistribution layer 46. An exposed lateral interconnect 50 is defined by a dielectric aperture 48 in the third dielectric layer 52 and provides an opening from the lateral interconnect 50 to a redistribution layer backside 51. The lateral interconnect 50 is also referred to as a redistributed surface interconnect.

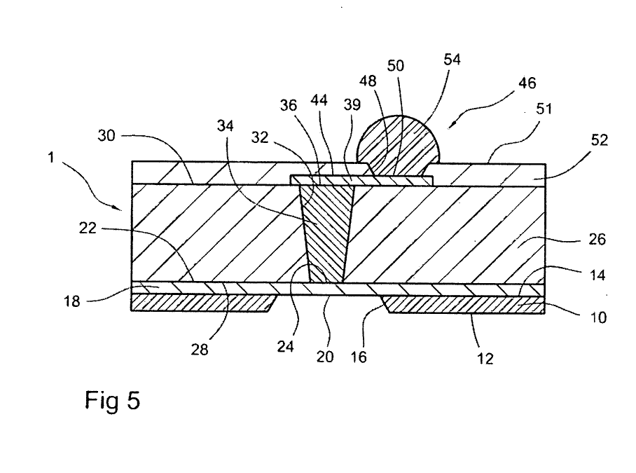

FIG. 5 is a side cross-sectional view of the die 1 of FIG. 4 showing the resulting lateral interconnect 50 provided with conductive interconnect material 54, in accordance with an embodiment of the invention. The interconnect material 54 is as described herein and may comprise a material such as, but not limited to, reflowable lead and lead-free solder and electrically conductive adhesive.

The lateral interconnect 50 may be very small, on the scale of 0.06 mm. Methods of applying interconnect material 54 in the form of solder and electrically conductive adhesive onto the lateral interconnect 50 are known in the art, such as, but not limited to, screen-printing.

In one embodiment in accordance with the present invention, the interconnect material 54 is provided on the lateral interconnect 50 by, for example, a screen printing process. The screen printing process involves electroless deposition of an interconnect material-compatible seed layer (not shown) onto the lateral interconnect 50, in instances wherein the lateral interconnect 50 is comprised of a material incompatible with the interconnect material 54. A screen having apertures corresponding to the lateral interconnect 50 is provided. Interconnect material 54 is passed through the apertures in the screen and onto the lateral interconnect 50. A reflow process is used to soften or melt the interconnect material 54 to form rounded interconnects in integral contact with the lateral interconnect 50 upon cooling.

In another embodiment in accordance with the present invention, the interconnect material 54 is provided on the lateral interconnect 50 by, for example, C4 bump processing. The C4 bump process involves deposition of an interconnect material-compatible seed layer (not shown) onto the lateral interconnect 50, in instances wherein the lateral interconnect 50 is comprised of a material incompatible with the interconnect material 54. A mask is provided on the redistribution layer backside 51 to expose only the lateral interconnect 50. A plating process may be used to deposit the interconnect material 54, which may include reflowable solder, onto the seed layer, if any, that is on the lateral interconnect 50. The mask and seed layer not covered by the interconnect material 54 is removed. A reflow process may be used to soften or melt the interconnect material 54 to form spherical interconnects, due to surface tension of the molten interconnect material 54, and establish an integral bond with the lateral interconnect 50 upon cooling.

Though not shown, it can be appreciated that other processes for interconnecting micro-components that do not use reflowable interconnects (e.g. electroplated Cu, electroless plated NiAu, and the like) may be used in accordance with embodiments of the present invention. Where such interconnects are used, processes including, but not limited to, thermal compression bonding (TCB) or ultrasonic bonding (uSB) may be used for interconnecting micro components.

In yet another embodiment in accordance with the present invention, the interconnect material 54 is provided on the lateral interconnect 50 by, for example, the deposition of an electrically conductive adhesive screen printing and onto the lateral interconnect 50. Electrically conductive adhesives are readily available, such as silver-loaded epoxy, that provides an interconnect material that does not necessarily require a high temperature curing process.

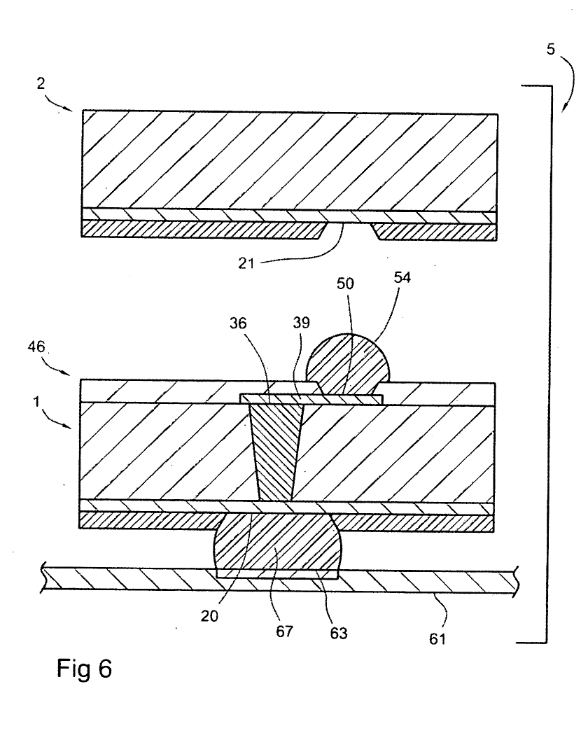

FIG. 6 is a side cross-sectional exploded view of a semiconductor device 5, in accordance with an embodiment of the invention, comprising a substrate 61, a first die 1, and a second die 2. The first die 1, made in accordance with the embodiment of FIG. 5, comprises a redistribution layer 46. The first die 1 is interconnected with a bond pad 63 on the substrate 61 with conductive interconnect material 67. During a reflow process, for example, the interconnect material 67 melts to form a unitary electrical interconnection between the active side interconnect 20 and the bond pad 63. The semiconductor device 5 further comprises a second die 2 interconnected with the redistribution layer 46. The backside interconnect 36 is not in lateral alignment with the second die interconnect 21 of the second die 2. The redistribution layer 46 provides a lateral conductive trace 39 that extends to a lateral position and provides a lateral interconnect 50 corresponding to and in lateral alignment with the second die interconnect 21. Direct interconnection between the lateral interconnect 50 and second die interconnect 21 using interconnect material 54 can thus be provided. During a reflow process, the interconnect material 54 melts and forms a unitary electrical interconnection between second die interconnect 21 and the lateral interconnect 50.

Embodiments in accordance with the present invention are suitable for numerous applications. Such applications include, but are not limited to, substrate to substrate retrofitting, and internal metal layer to surface layer retrofitting, cap wafer to interconnect retrofitting and array retrofitting.

It is understood that the embodiments of the present invention can be applied in a general sense and not constrained to those configurations as shown in the figures. The embodiments of the present invention are applicable regardless of the general positioning of the micro-components. For example, but not limited thereto, the embodiment as shown in FIG. 6 is applicable whether the components are as shown, or turned upside-down.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

1. A substrate having an active side and a back side, comprising:
an active side interconnect disposed on the active side;
a backside interconnect disposed on the backside, coupled to and in substantial vertical alignment with the active side interconnect; and
a redistributed interconnect of the backside interconnect disposed on the backside, coupled to and offset from the backside interconnect.

2. The substrate of claim 1, further comprising:
a metal layer having a first side and a second side;
a first dielectric layer adjacent to the first side of the metal layer;
a first aperture in the first dielectric layer, the first aperture exposing a portion of the first side of the metal layer to define the active side interconnect;
a second dielectric layer adjacent to the second side of the metal layer; and
a via extending from the backside interconnect through the second dielectric layer to the second side of the metal layer to electrically couple the backside interconnect to the metal layer.

3. The substrate of claim 1, wherein the redistributed interconnect comprises:
a conductive trace coupled to and extending from the backside interconnect to a selected location;
a third dielectric layer overlaying the conductive trace; and an aperture in the third dielectric layer substantially at or near the selected location.

4. The substrate of claim 3, wherein the selected location for the redistributed interconnect corresponds to an interconnect on a second substrate.

5. The substrate of claim 1, wherein the redistributed interconnect is not in vertical alignment with the backside interconnect.

6. A semiconductor device, comprising:
a carrier substrate having a bond pad;
a first substrate, the first substrate comprising
an active side and a back side;
an active side interconnect, the active side interconnect disposed on the active side, coupled to the bond pad of the carrier substrate;
a backside interconnect disposed on the back side, coupled to and in substantial vertical alignment with the active side interconnect;
a redistributed interconnect of the backside interconnect, disposed on the backside, coupled to and offset from the backside interconnect; and
a second substrate electrically coupled to the redistributed interconnect of the first substrate.

7. The semiconductor device of claim 6, wherein the first substrate comprises:
a metal layer having a first side and a second side;
a first dielectric layer adjacent to the first side of the metal layer;
a first aperture in the first dielectric layer, the first aperture exposing a portion of the first side of the metal layer to define the active side interconnect;
a second dielectric layer adjacent to the second side of the metal layer; and
a via extending from the backside interconnect through the second dielectric layer to the second side of the metal layer to electrically couple the backside interconnect to the metal layer.

8. The semiconductor device of claim 6, wherein the redistributed interconnect comprises:
a conductive trace coupled to and extending from the backside interconnect to a selected location;
a third dielectric layer overlaying the conductive trace; and
an aperture in the third dielectric layer at the selected location.

9. The semiconductor device of claim 8, wherein the selected location for the redistributed interconnect corresponds to an interconnect on the second substrate.

10. The semiconductor device of claim 6, wherein the first substrate and the second substrates are microelectronic dies.

11. The semiconductor device of claim 6, wherein the second substrate is coupled to the redistributed interconnect by a process selected from the group including reflow bonding, thermal compression bonding or ultrasonic bonding.

12. The semiconductor device of claim 6, wherein the redistributed interconnect is not in vertical alignment with the backside interconnect.

13. A method comprising:
providing an active side interconnect to an active side of a substrate;
providing a backside interconnect to a back side of the substrate with the backside interconnect being coupled to and in substantial vertical alignment with the active side interconnect; and
providing a redistributed interconnect of the backside interconnect on the backside, the redistributed interconnect being coupled to and offset from the backside interconnect.

14. The method of claim 13, wherein providing the redistributed interconnect comprises:
depositing a conductive trace on the back side;
coupling the conductive trace to the backside interconnect;
extending the conductive trace to a selected location;
placing a third dielectric layer over the conductive trace; and
forming an aperture in the third dielectric layer at the selected location.

15. The method of claim 13, wherein providing the backside interconnect comprises forming a via that extends from the backside interconnect through a second dielectric layer to a metal layer and filling the via with an electrically conductive material.

16. The method of claim 13, further comprising;
providing a carrier substrate having a bond pad
providing a second substrate having an interconnect;
coupling the active side interconnect to the carrier substrate bond pad; and
coupling the interconnect of the second substrate to the redistributed interconnect.

17. The method of claim 16, wherein coupling the interconnect of the second substrate to the redistributed interconnect is performed by a process selected from the group including reflow bonding, thermal compression bonding or ultrasonic bonding.

18. A method for redistributing interconnects, comprising:
providing a substrate having an active side and a backside, the active side having an active side interconnect;
forming a via in the backside extending from a surface of the backside to a metal layer within the substrate;
filling the via with an electrically conductive material such that a backside interconnect is formed at or substantially near the surface of the backside and in electrical communication with the metal layer;
depositing a conductive trace on the backside surface such that the conductive trace extends from the backside interconnect to a selected location on the back side surface;
depositing a dielectric layer on the back side surface such that it overlays the conductive trace; and
defining a redistributed interconnect of the backside interconnect at the selected location.

19. The method of claim 18, wherein defining the redistributed interconnect comprises forming an aperture in the dielectric layer at the selected location to expose a portion of the conductive trace.

20. The method of claim 19, wherein forming the aperture comprises etching a portion of the dielectric layer at the selected location to expose a portion of the conductive trace.

21. The method of claim 18, further comprising choosing the selected location to correspond to a location of a complementary interconnect of a substrate in facing relationship there with.

22. The method of claim 18, wherein depositing the conductive trace comprises forming a patterned electrically conductive layer on the backside surface using a photolithography process.

23. The method of claim 18, further comprising depositing a conductive interconnect material into the dielectric aperture such that the conductive interconnect material is coupled to the redistributed interconnect and extends above the dielectric layer.

24. The method of claim 18, further comprising;
providing a carrier substrate having a bond pad;
providing a second substrate having an interconnect;
coupling the active side interconnect to the carrier substrate bond pad; and
coupling the interconnect of the second substrate to the redistributed interconnect.

25. The method of claim 24, wherein coupling the interconnect of the second substrate to the redistributed interconnect is performed by a process selected from the group including reflow bonding, thermal compression bonding or ultrasonic bonding.
